(19) United States
(12) Patent Application Publication
(10) Pub. No.: US 2025/0300672 A1
(43) Pub. Date: Sep. 25, 2025

(54) ENHANCED POSIT REPRESENTATION

(71) Applicant: Huawei Technologies Co., Ltd., Shenzhen (CN)

(72) Inventors: Wei Wang, San Jose, CA (US); Yue Chen, Saratoga, CA (US)

(21) Appl. No.: 19/233,839

(22) Filed: Jun. 10, 2025

Related U.S. Application Data
(63) Continuation of application No. PCT/US2023/085766, filed on Dec. 22, 2023.
(60) Provisional application No. 63/434,794, filed on Dec. 22, 2022.
(60) Provisional application No. 63/493,908, filed on Apr. 3, 2023.

(51) Int. Cl. H03M 7/40

(52) U.S. Cl. CPC H03M 7/4068

(57) ABSTRACT

A method for converting a signed real number to an n-bit exponential Posit format number implemented by an exponential Posit coding device. The method comprises: i) receiving the signed real number in the exponential Posit coding device; ii) representing a sign of the signed real number with an s bit; iii) representing a scale factor of the signed real number by a prefix comprising a plurality of regime bits; and iv) representing the scale factor of the signed real number by a suffix comprising a plurality of exponent bits to generate the n-bit exponential Posit format number.

### CROSS-REFERENCE TO RELATED APPLICATIONS

This is a continuation of International Application No. PCT/US2023/085766, filed Dec. 22, 2023, entitled “Enhanced Posit Representation,” which claims the benefit of U.S. Provisional Patent No. 63/434,794, filed Dec. 22, 2022, entitled “NEURAL NETWORK DYNAMIC QUANTIZATION, UNIFICATION AND SPARSITY,” and U.S. Provisional Patent No. 63/493,908, filed Apr. 3, 2023, entitled “ENHANCED POSIT REPRESENTATION,” all of which are hereby incorporated by reference in their entireties.

### BACKGROUND

Posit arithmetic is a type of number representation proposed by John Gustafson as an alternative to traditional floating-point arithmetic. Posit numbers use a unique encoding scheme that allows them to represent a wide range of numbers with a small number of bits. Posits are designed to address certain limitations and challenges associated with floating-point arithmetic, which is commonly used in computing. Unlike fixed-size floating-point formats (e.g., 32-bit or 64-bit), posits can dynamically adjust their bit size based on the magnitude of the number. This allows for increased precision for small numbers and a wider dynamic range for large numbers. Posits aim to minimize certain types of errors that can accumulate in traditional floating-point arithmetic, such as rounding errors and overflow issues. The dynamic range adjustment helps in representing both very large and very small numbers more accurately. Posits are designed to be more efficient in terms of both hardware utilization and energy consumption compared to floating-point arithmetic. This efficiency is particularly relevant in high-performance computing and supercomputing environments. Posits maintain certain desirable mathematical properties while addressing some of the limitations of traditional floating-point arithmetic.

### SUMMARY

A first aspect relates to a method for converting a signed real number to an n-bit exponential Posit format number implemented by an exponential Posit coding device. The method comprises: i) receiving the signed real number in the exponential Posit coding device; ii) representing a sign of the signed real number with an s bit; iii) representing a scale factor of the signed real number by a prefix comprising a plurality of regime bits; and iv) representing the scale factor of the signed real number by a suffix comprising a plurality of exponent bits to generate the n-bit exponential Posit format number.

Optionally, in the preceding aspect, another implementation of the aspect further includes storing the n-bit exponential Posit format number in a memory by the exponential Posit coding device, wherein storage of the n-bit exponential Posit format number in the memory uses less bits than storage of the signed real number in the memory.

Optionally, in any of the preceding aspects, another implementation of the aspect further includes transmitting, by the exponential Posit coding device, the n-bit exponential Posit format number toward a decoding device, wherein transmission of the n-bit exponential Posit format number uses less bandwidth than transmission of the signed real number.

Optionally, in any of the preceding aspects, another implementation of the aspect includes representing a fraction of the signed real number with a plurality of fraction bits.

Optionally, in any of the preceding aspects, another implementation of the aspect includes wherein the regime bits include an integer value and a regime sign.

Optionally, in any of the preceding aspects, another implementation of the aspect includes wherein the n-bit exponential Posit format has the structure

| | regime bits | | | | | exponent | | | | | | | | |
|---|---|---|---|---|---|---|---|---|---|---|---|---|---|---|
| | re- | | | | stop | bits, | | | | | | | | |
| | gime | run | | | bit, | if any (ees = | | | | fraction | | | | |
| sign | sign | (r bits) | | | if any | es + r bits) | | | | bits, if any | | | | |
| s | sᵣ | r | r | . . . | r̅ | e₁ | e₂ | . . . | eₑₑₛ | f₁ | f₂ | f₃ | f₄ | . . . |

n bits

A second aspect relates to a method for converting an integer number to an n-bit integer Posit format number implemented by an exponential Posit coding device, comprising: i) receiving the integer number in the exponential Posit coding device; ii) representing a sign of the integer number with an s bit; iii) representing a shift factor of the integer number by a prefix comprising a plurality of regime bits; and iv) representing the shift factor of the integer number by a suffix comprising a plurality of exponent bits to generate the n-bit exponential Posit format number.

Optionally, in the preceding aspect, another implementation of the aspect further comprises representing a fraction of the integer number with a plurality of fraction bits.

Optionally, in any of the preceding aspects, another implementation of the aspect includes wherein the regime bits comprise an unsigned integer value and the exponent bits represent an unsigned integer.

Optionally, in any of the preceding aspects, another implementation of the aspect includes wherein the n-bit exponential Posit format has the structure:

| | regime bits | | | | | | | | | | | | |
|---|---|---|---|---|---|---|---|---|---|---|---|---|---|
| | (R = r + 1 bits) | | | | exponent | | | | | | | | |
| | run | | | stop bit, | bits, if any | | | | fraction | | | | |
| sign | (r bits) | | | if any | (es bits) | | | | bits, if any | | | | |
| s | r | r | . . . | r̅ | e₁ | e₂ | . . . | eₑₛ | f₁ | f₂ | f₃ | f₄ | . . . |

n bits

A third aspect relates to an apparatus for converting a signed real number to an n-bit exponential Posit format number, comprising: i) a storage device; and ii) one or more processors coupled to the storage device and configured to execute instructions on the storage device. When executed, the instructions cause the apparatus to: iii) receive the signed real number in the apparatus; iv) represent a sign of the signed real number with an s bit; v) represent a scale factor of the signed real number by a prefix comprising a plurality of regime bits; and vi) represent the scale factor of the signed real number by a suffix comprising a plurality of exponent bits to generate the n-bit exponential Posit format number.

Optionally, in the preceding aspect, another implementation of the aspect includes wherein the instructions when executed further cause the apparatus to store the n-bit exponential Posit format number in a memory, wherein storage of the n-bit exponential Posit format number in the memory uses less bits than storage of the signed real number in the memory.

Optionally, in any of the preceding aspects, another implementation of the aspect includes wherein the instructions when executed further cause the apparatus to transmit, by an encoding device, the n-bit exponential Posit format number toward a decoding device, wherein transmission of the n-bit exponential Posit format number uses less bandwidth than transmission of the signed real number.

Optionally, in the preceding aspect, another implementation of the aspect includes wherein the instructions when executed further cause the apparatus to represent a fraction of the signed real number with a plurality of fraction bits.

Optionally, in the preceding aspect, another implementation of the aspect includes wherein the regime bits include an integer value and a regime sign.

Optionally, in any of the preceding aspects, another implementation of the aspect includes wherein the n-bit exponential Posit format has the structure:

| | | | | | | exponent | | | | | | | | |
|---|---|---|---|---|---|---|---|---|---|---|---|---|---|---|
| | regime bits | | | | | bits, if any | | | | | | | | |
| | re- | | | | stop | (ees = | | | | fraction | | | | |
| | gime | run | | | bit, | es + r | | | | bits, if | | | | |
| Sign | sign | (r bits) | | | if any | bits) | | | | any | | | | |
| s | sᵣ | r | r | . . . | r̅ | e₁ | e₂ | . . . | eₑₑₛ | f₁ | f₂ | f₃ | f₄ | . . . |

n bits

A fourth aspect relates to an apparatus for converting an integer number to an n-bit integer Posit format. The apparatus comprises: i) a storage device; and ii) one or more processors coupled to the storage device and configured to execute instructions on the storage device such that when executed, cause the apparatus to: iii) receive the integer number in the apparatus; iv) represent a sign of the integer number with an s bit; v) represent a shift factor of the integer number by a prefix comprising a plurality of regime bits; and vi) represent the shift factor of the integer number by a suffix comprising a plurality of exponent bits to generate the n-bit exponential Posit format number

Optionally, in the preceding aspect, another implementation of the aspect further includes wherein execution of the instructions further cause the apparatus to represent a fraction of the integer number with a plurality of fraction bits.

Optionally, in the preceding aspect, another implementation of the aspect further includes wherein the regime bits comprise an unsigned integer value and the exponent bits represent an unsigned integer.

Optionally, in any of the preceding aspects, another implementation of the aspect includes wherein the n-bit exponential Posit format has the structure:

| | regime bits | | | | | | | | | | | | |
|---|---|---|---|---|---|---|---|---|---|---|---|---|---|
| | (R = r + 1 bits) | | | | exponent | | | | | | | | |
| | run | | | stop bit, | bits, if any | | | | fraction | | | | |
| sign | (r bits) | | | if any | (es bits) | | | | bits, if any | | | | |
| s | r | r | . . . | r̅ | e₁ | e₂ | . . . | eₑₛ | f₁ | f₂ | f₃ | f₄ | . . . |

n bits

A fifth aspect relates to a non-transitory computer readable medium comprising a computer program product for use by a network node, the computer program product comprising computer executable instructions stored on the non-transitory computer readable medium that, when executed by one or more processors, cause the network node to execute the method of any of the preceding aspects.

### BRIEF DESCRIPTION OF THE DRAWINGS

For a more complete understanding of the present disclosure, reference is now made to the following brief description, taken in connection with the accompanying drawings and detailed description, wherein like reference numerals represent like parts.

FIG. 1 is a table illustrating EGk binarization according to an embodiment of the disclosure.

FIG. 2 is a table illustrating an example of 8-bit IPosit according to an embodiment of the disclosure.

FIG. 3 is a table illustrating another example of 8-bit IPosit according to an embodiment of the disclosure.

FIG. 4 is a table illustrating example of 8-bit EIPosit according to an embodiment of the disclosure.

FIG. 5 is a table illustrating another example of 8-bit EIPosit according to an embodiment of the disclosure.

FIG. 6A illustrates weight pruning according to an embodiment of the disclosure.

FIG. 6B illustrates weight quantization according to an embodiment of the disclosure.

FIG. 6C illustrates structured unification loss optimization according to an embodiment of the disclosure.

FIG. 6D illustrates low rank factorization according to an embodiment of the disclosure.

FIG. 7 illustrates dynamic quantization according to an embodiment of the disclosure.

FIG. 8 illustrates Location M and N bits according to an embodiment of the disclosure.

FIG. 9 illustrates an example of a predefined uniform patterns structure according to an embodiment of the present disclosure.

FIG. 10 is a schematic diagram of a routing device according to an embodiment of the disclosure.

FIG. 11 is a flowchart of a method for converting a signed real number to an n-bit exponential Posit format number according to an embodiment of the disclosure.

### DETAILED DESCRIPTION

The present disclosure is related to methods and apparatuses for encoding and decoding enhanced Posit representation. More specifically, the method is related to Exponential Posit representation, Integer Posit representation, and Unification based Integer Posit representation. According to the principles of the present disclosure, the enhanced Posit representation may be implemented as an encoding and decoding algorithm executed by processors, logic units, or central processing units (CPUs) of conventional computer. The enhanced Posit representations may be stored in a memory of the computers.

From a binarization method point of view, the scale factor in current Posit format is represented by a k-th order truncated Golomb-Rice (TRk) binarization. However, this binarization method is not the most efficient binarization method in all situations. When the dynamic range of the numbers is not large, precision may be sacrificed in smaller numbers in order to support an unnecessarily large dynamic range. The present disclosure proposes a unique binarization method to represent scale factor to further increase the dynamic range of Posit representation in practical applications including high-performance computing and supercomputing environments. The present disclosure describes a method of converting a real signed number to a Posit number in a manner that overcomes the drawbacks noted above. By generating the Posit number using the disclosed embodiments, the number of bits needed to store and/or transmit the Posit number is reduced relative to storage and/or transmission of a real signed number. Thus, the use of network and hardware resources is improved.

Binarization Methods-Binarization is a process to map an integer value to a binary codeword so that its representation can match with the entropy distribution of the system. Fixed Length (FL) binarization represents a non-negative integer x by a fixed length binary string where the length is fixed to ceil (log₂(cMax)), where cMax is the max value. Unary binarization represents a non-negative integer x by a binary string of x 1's followed by a 0. Truncated unary (TU) binarization is a special case of Unary binarization where the last 0 is truncated (removed) in case of x=cMax.

A k-th order Golomb-Rice (GRk) binarization represents a non-negative integer x by a prefix p and a suffix s. Prefix p has a Unary representation and suffix s has a FL representation. The length of suffix s is the value of Rice parameter k. If Rice parameter k=0, then there is no suffix and GRk binarization is equivalent to Unary binarization.

$$p = x ≫ k$$

$$s = x - ( p ≪ k )$$

A k-th order truncated Golomb-Rice (TRk) binarization is a special case of GRk binarization, where the prefix p is generated using TU instead of Unary binarization. If Rice parameter k=0, then there is no suffix and TRk binarization is equivalent to TU binarization. A k-th order Exp-Golomb (EGk) binarization is an exponential variation of GRk binarization where the length of suffix s doubles after each bit in the Unary code of prefix p. Therefore, the length of EGk codes grows slower than that of GRk codes. To encode a non-negative integer x using the EGO (EGk, k=0) binarization: i) Write down x+1 in binary, and ii) Count the bits written, subtract one, and write that number of starting zero bits preceding the previous bit string. To encode a non-negative integer x in an EGk (EGk, k≠0) binarization: i) Encode x>>k using EGO code, then ii) Encode×mod 2k in binary. A k-th order truncated Exp-Golomb (TEGk) binarization is a special case of EGk binarization where the prefix is generated using TU instead of Unary binarization.

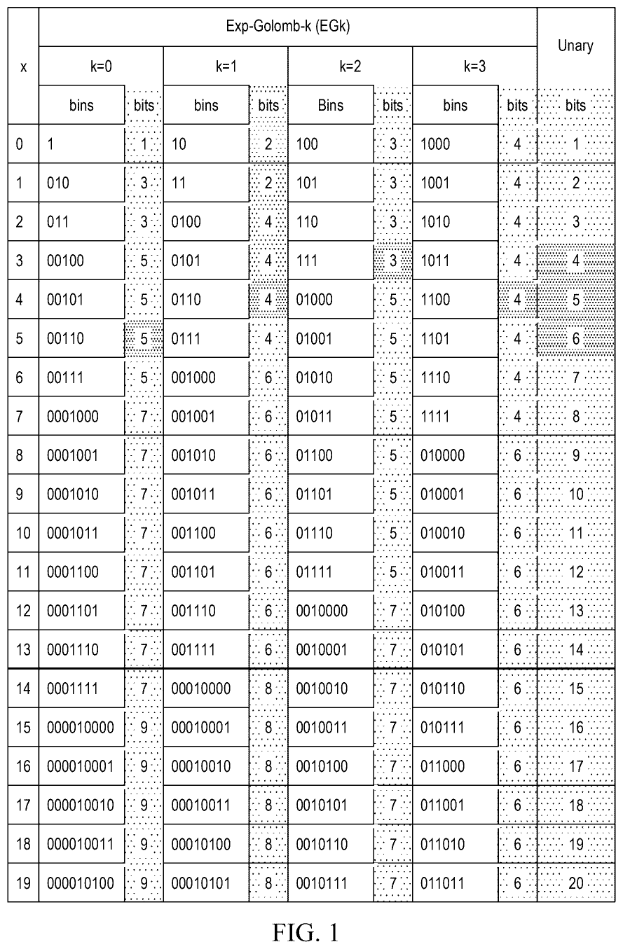

FIG. 1 is a table illustrating EGk binarization according to an embodiment of the disclosure. It is apparent from the EGk binarization example that low k values are better for near-zero peaked distributions and high values of k are better for long-tail distributions. One option to encode a non-Positive integer x is to map it to an even integer−2x, while a Positive integer x is mapped to an odd integer 2x−1. Another option to encode a non-Positive integer x is to encode the sign bit first, followed by the absolute value −x

Posit Format-Posit format is an alternative to the standard Institute of Electrical and Electronics Engineers (IEEE) 754 floating point format for representing real numbers. Posit format represents more precision or dynamic range and uses less storage and bandwidth. Its precision property for real numbers is also suitable for Deep Learning and other applications.

The structure of an n-bit Posit representation with es exponent bits is illustrated below:

| | regime bits | | | | | exponent | | | | | | | | |
|---|---|---|---|---|---|---|---|---|---|---|---|---|---|---|
| | re- | | | | stop | bits, | | | | fraction | | | | |
| | gime | run | | | bit, | if any | | | | bits, if | | | | |
| sign | sign | (r bits) | | | if any | (es bits) | | | | any | | | | |
| s | sᵣ | r | r | . . . | r̅ | e₁ | e₂ | . . . | eₑₛ | f₁ | f₂ | f₃ | f₄ | . . . |

n bits

### Posit Format

Assuming a signed real number x is represented by an n-bit Posit and its scale factor is represented by a prefix (regime bits) and a suffix (exponent bits). Let p be the integer represented by the regime bits, s (if any) be the unsigned integer represented by the exponent bits, and f (if any) be the fraction (1.f₁f₂f₃f₄ . . . ). Then x is represented as:

$$x = \{ \begin{matrix}0 , & x = 00 …0 \\ \pm ∞ , & x = 10 …0 \\ sign ( x ) \times {useed}^{p} \times {2}^{s} \times f , & all other x\end{matrix}$$

A parameter useed is defined as: useed=2²^{^{es}}.

| es | 0 | 1 | 2 | 3 | 4 |
|---|---|---|---|---|---|
| useed | 2 | 4 | 16 | 256 | 65536 |

### Useed Representation

Take a 5-bit Posit as an example. The prefix p and corresponding regime bins are illustrated here, the “x” is used for exponent bits (if any) and fraction bits (if any):

| regime bins | 10xx | 110x | 1110 | 1111 |
|---|---|---|---|---|
| P | 0 | 1 | 2 | 3 |
| regime bins | 01xx | 001x | 0001 | 0000 |
| P | −1 | −2 | −3 | −4 |

### Regime Binarization

Regime bits are the TU binarization of p (pcMax=n−2=3).

$$p = \{ \begin{matrix}r , & {s}_{r} = 1 \\ - ( r + 1 ) , & {s}_{r} = 0\end{matrix}$$

The suffix s has es bits, but one or more or all bits may be beyond the n-bit limit and thus have value 0. The value represented by suffix has limited range if one or more or all bits are beyond the n-bit limit and assigned with value 0. Exponent bits are the FL binarization of s and the length of the binary string is fixed to es. The remaining bits after exponent bits (if any) are used for fraction which is represented by the set of fraction bits {f₁, f₂, f₃, f₄, . . . }. There are two exceptions in Posit representation. A string of n 0's represents the number zero, and a 1 followed by n−1 0's represents ±∞.

As can be seen from Posit representation, the log₂ of scale factor(S) of x can be written as:

$$LgS = {log}_{2} ( {useed}^{p} \times {2}^{s} ) = p \times {2}^{es} + s$$

Since p is represented by TU binarization and s is represented by FL binarization where the length of the binary string is fixed to es, LgS is represented by TRk binarization (pcMax=n−2, k=es). The TRk binarization of scale factor is very efficient to represent tapered accuracy because it uses less bits for small numbers and more bits for large numbers; x near 1, assigned with more fraction bits, have more accuracy than extremely large or extremely small numbers which are assigned with less fraction bits.

The log₂ of scale factor in Posit format is represented by TRk binarization (pcMax=n−2, k=es). The TEGk codes grow slower than GRk codes, which means that TEGk codes can provide more dynamic range than TRk codes. Compared to real number representation, integer number representation has different considerations, where quantization accuracy is more important than dynamic range. Posit representation is for real numbers only and cannot be used for integer number representation. There is also a need to design a representation for a group of integers.

### Exponential Posit (EPosit)—

The table below illustrates the codeword length difference between GRk and EGk binarization:

| GRk p₁ | 0 | 1 | 2 | 3 | 4 | 5 | 6 | 7 | 8 | 9 | 10 | 11 | 12 | 13 | 14 | 15 | 16 | . . . |
|---|---|---|---|---|---|---|---|---|---|---|---|---|---|---|---|---|---|---|
| GRk | 2^{k} | 2^{k} | 2^{k} | 2^{k} | 2^{k} | 2^{k} | 2^{k} | 2^{k} | 2^{k} | 2^{k} | 2^{k} | 2^{k} | 2^{k} | 2^{k} | 2^{k} | 2^{k} | 2^{k} | . . . |
| size | | | | | | | | | | | | | | | | | | |

| | | | | | |
|---|---|---|---|---|---|
| EGk p₂ | 0 | 1 | 2 | 3 | 4 |

| | | | | | |
|---|---|---|---|---|---|
| EGk | 2^{k} | 2^{k+1} | 2^{k+2} | 2^{k+3} | 2^{k+4} . . . |
| size | | | | | |

### GRk and EGk Binarization

For a non-negative integer x, the total bit-length is 1+k+p₁ for GRk binarization (p₁, s) and the total bit-length is 1+k+2*p₂ for EGk binarization (p₂, s). EGk binarization is more efficient than GRk binarization in most cases.

The present disclosure introduces an exponential Posit format (EPosit) as an enhanced Posit format to further increase the dynamic range of Posit representation. The disclosed enhanced Posit format uses TEGk binarization instead of TRk binarization to represent LgS in EPosit format.

The structure of an n-bit EPosit representation with ees exponent bits is illustrated here:

| | regime bits | | | | | exponent | | | | | | | | |
|---|---|---|---|---|---|---|---|---|---|---|---|---|---|---|
| | re- | | | | stop | bits, if any | | | | fraction | | | | |
| | gime | run | | | bit, | (ees = es + | | | | bits, if | | | | |
| sign | sign | (r bits) | | | if any | r bits) | | | | any | | | | |
| s | sᵣ | r | r | . . . | r̅ | e₁ | e₂ | . . . | eₑₑₛ | f₁ | f₂ | f₃ | f₄ | . . . |

n bits

### EPosit Format

Assume a signed real number x is represented by n-bit EPosit and its scale factor is represented by a prefix (regime bits) and a suffix (exponent bits). Let p be the integer represented by the regime bits, s (if any) be the unsigned integer represented by the exponent bits, and f (if any) be the fraction (1.f₁f₂f₃f₄ . . . ).

In one embodiment, x is represented using original Posit definition:

$$x = \{ \begin{matrix}0 , & x = 00 …0 \\ \pm ∞ , & x = 10 …0 \\ sign ( x ) \times {useed}^{ep} \times {2}^{s} \times f , & all other x\end{matrix}$$

A parameter useed is defined as: useed=2²^{^{es}}.

Regime bits are the TU binarization of p (pcMax=n−2).

$$p = \{ \begin{matrix}r , & {s}_{r} = 1 \\ - ( r + 1 ) , & {s}_{r} = 0\end{matrix}$$

A parameter ep is defined as:

$$ep = \{ \begin{matrix}{2}^{r} - 1 = {2}^{p} - 1 , & {s}_{r} = 1 \\ - ( {2}^{r + 1} - 1 ) = - ( {2}^{- p} - 1 ) , & {s}_{r} = 0\end{matrix}$$

In another embodiment, x is represented using simplified regime sign handling method:

$$x = \{ \begin{matrix}0 , & x = 00 …0 \\ \pm ∞ , & x = 10 …0 \\ sign ( x ) \times {useed}^{ep} \times {2}^{sign ( 1 - {s}_{r} ) \times s} \times f , & all other x\end{matrix}$$

A parameter useed is defined as: useed=2²^{^{es}}.

Regime bits are the TU binarization of p (pcMax=n−2).

$$p = \{ \begin{matrix}r , & {s}_{r} = 1 \\ - r , & {s}_{r} = 0\end{matrix}$$

A parameter ep is defined as:

$$ep = sign ( 1 - {s}_{r} ) \times ( {2}^{r} - 1 ) = \{ \begin{matrix}( {2}^{p} - 1 ) , & {s}_{r} = 1 \\ - ( {2}^{- p} - 1 ) , & {s}_{r} = 0\end{matrix}$$

The suffix s has ees bits, but one or more or all bits may be beyond the n-bit limit and thus have value 0. The value represented by suffix has limited range if one or more or all bits are beyond the n-bit limit and assigned with value 0. Exponent bits are the FL binarization of s and the length of the binary string is ees=es+r. The remaining bits after exponent bits (if any) are used for fractions which are represented by the set of fraction bits {f₁, f₂, f₃, f₄, . . . }.

There are two exceptions in EPosit representation: 1) a string of n 0s represents the number zero and 2) a 1 followed by n−1 0s represents ±∞. As can be seen from EPosit representation, the log₂ of scale factor(S) of x can be written as:

$$LgS = {log}_{2} ( {useed}^{ep} \times {2}^{sign ( 1 - {s}_{r} ) \times s} ) = sign ( 1 - {s}_{r} ) \times ( ( {2}^{r} - 1 ) \times {2}^{es} + s )$$

Since prefix p is represented by TU binarization and suffix s is represented by FL binarization, where the length of the binary string ees=k+r=es+r, then LgS is represented by TEGk binarization (pcMax=n−2, k=es).

The dynamic range for n-bit IEEE 754 format, Posit format, and EPosit format can be calculated by

$$IEEE 754 \text{:} {\frac{1}{2}}^{{2}^{es - 1} - 2} to {2}^{{2}^{es - 1}} , es = \{ \begin{matrix}5 , & n = 16 \\ 8 , & n = 64 \\ 11 , & n = 64 \\ 15 , & n = 128 \\ 19 , & n = 256\end{matrix}$$

$$Posit \text{:} \{ \begin{matrix}{\frac{1}{2}}^{( n - 2 ) \times {2}^{es}} to {2}^{( n - 2 ) \times {2}^{es}} , & partial es bits , limited dynamic range \\ {\frac{1}{2}}^{( n - 2 - es ) \times {2}^{es}} to {2}^{( n - 2 - es ) \times {2}^{es}} , & full es bits , full dynamic range\end{matrix}$$

$$EPosit \text{:} \{ \begin{matrix}1 / {2}^{( {2}^{n - 2} - 1 ) \times {2}^{es}} to {2}^{( {2}^{n - 2} - 1 ) \times {2}^{es}} , & partial ees bits , limited dynamic range \\ 1 / {2}^{( {2}^{n - 3 - es ) >> 2} - 1 ) \times {2}^{es}} to {2}^{( {2}^{n - 3 - es ) >> 2} - 1 ) \times {2}^{es}} , & full ees bits , full dynamic range\end{matrix}$$

In IEEE 754 format, LgS is represented by FL binarization, where the length of the binary string is fixed to k=es. In Posit format, LgS is represented by TRk binarization (pcMax=n−2, k=es), prefix p is represented by TU binarization, and suffix s is represented by FL binarization where the length of the binary string is fixed to k=es. In the disclosed exponential EPosit format, LgS is represented by TEGk binarization (pcMax=n−2, k=es), prefix p is represented by TU binarization, and suffix s is represented by FL binarization, where the length of the binary string is ees=k+r=es+r.

From the view of binarization methods: i) IEEE 754 format uses FL binarization and provides limited dynamic range; ii) Posit format uses TRk binarization and provides more linearly increased dynamic range than that of IEEE 754 format; and iii) EPosit format uses TEGk binarization and provides more exponentially increased dynamic range than that of Posit format.

### Tapered Accuracy Integer Representation

Compared to real number representation, integer number representation has different considerations where quantization accuracy is more important than dynamic range. When a real number x is quantized to an integer number, the quantization error is fixed to the scale factor. Like IEEE 754 for floating number representation, FL binarization of integer number is not very efficient to represent tapered accuracy. However, tapered accuracy integer representation is very useful for some applications such as Neural Network where the weight distribution in a layer usually follows Gaussian style bell shape distribution and the percentage of smaller coefficients is more than that of larger coefficients.

For simplicity, it is assumed an m-bit signed integer number qₘ is represented by sign-and-magnitude representation. It is desirable to find an integer representation that achieves tapered accuracy when a n-bit signed integer number qₙ is used to approximate a m-bit (n<m) signed integer number qₘ. The present disclosure represents qₙ with a set {sign, sft, fra} where the bit length of sign is 1 bit, the bit length of sft is e bits, and the bit length of fra (BLF) is n−1-e bits.

| bit location | m-1 | . . . | . . . | 12 | 11 | 10 | 9 | 8 | 7 | 6 | 5 | 4 | 3 | 2 | 1 | 0 |
|---|---|---|---|---|---|---|---|---|---|---|---|---|---|---|---|---|
| m-bit qₘ | sign | 0 | 0 | 0 | 0 | 0 | 0 | 0 | 0 | 0 | 0 | 0/1 | x | x | x | x |
| n-bit qₙ | LO < n-1-e | | | | | | | | S | e₁ . . . eₑ | | f₁ | f₂ | f₃ | . . . | fₙ₋₁₋ₑ |
| m-bit qₘ | sign | 0 | 0 | 0 | 0 | 0 | 0 | 0 | 1 | x | x | x | x | x | x | x |

| | | | | | | |
|---|---|---|---|---|---|---|
| n-bit qₙ | LO >= n-1-e | s | e₁ . . . eₑ | f₁ | . . . | fₙ₋₁₋ₑ |

### Tapered Accuracy Integer Representation

Let LO be the bit location of leading one in qₘ and TO be the bit location of trailing one in qₘ where TO==LO indicates that there is no trailing one in qₘ. If LO<BLF then parameter fra (f₁f₂f₃ . . . fₙ₋₁₋ₑ) is represented by last BLF adjacent bits of qₘ, otherwise, fra (f₁f₂f₃ . . . fₙ₋₁₋ₑ) is represented by BLF adjacent bits (starting from bit location LO−1) of qₘ. When LO>=BLF, because the leading one can be inferred, the full fraction is represented by (1′fra).

Parameter sft indicates the bit location of the first bit of fra in qₘ, so it can be used to shift fra to the correct location of qₘ. Sft is set to 0 when LO<BLF and no shifting of fra is required, otherwise, sft=LO−BLF and fra is left shifted by sft bits. The range of sft is limited to [0, m−n+e].

Tapered accuracy is achieved using the proposed format. Representation error decreases when LO decreases, which means that representation error is large for integer number with large LO, and representation error is small for integer number with small LO. For integer number whose LO<BLF or for integer number whose LO−TO+1<BLF, the representation error is zero and the full representation accuracy is maintained.

Integer Posit (or IPosit)—The present disclosure introduces an integer Posit format (IPosit) to represent integer numbers and uses TRk binarization to represent shift factor. The structure of an n-bit IPosit representation with es exponent bits is illustrated below:

| | regime bits | | | | exponent | | | | | | | | |
|---|---|---|---|---|---|---|---|---|---|---|---|---|---|
| | (R = r + 1 bits) | | | | bits, | | | | | | | | |
| | run | | | stop bit, | if any | | | | fraction | | | | |
| sign | (r bits) | | | if any | (es bits) | | | | bits, if any | | | | |
| s | r | r | . . . | r̅ | e₁ | e₂ | . . . | eₑₛ | f₁ | f₂ | f₃ | f₄ | . . . |

n bits

### IPosit Format

Assuming a signed number x is represented by n-bit IPosit and its shift factor is represented by a prefix (regime bits) and a suffix (exponent bits). Let p be the unsigned integer represented by the regime bits, s (if any) be the unsigned integer represented by the exponent bits, and f (if any) be the fraction (f₁f₂f₃f₄ . . . or 1′f₁f₂f₃f₄ . . . ). Then x can be represented by left shift factor (LS) and right shift factor (RS) as:

$$x = sign ( x ) \times ( ( f << LS ) >> RS )$$

Or x can be represented by a unified left shift factor ULS as:

$$x = sign ( x ) \times ( f << ULS )$$

Regime bits are the TU binarization of p=r (pcMax=n−1). The suffix s has es bits, but one or more or all bits may be beyond the n-bit limit and thus have value 0. The value represented by suffix has limited range if one or more or all bits are beyond the n-bit limit and assigned with value 0. Exponent bits are the FL binarization of s and the length of the binary string is fixed to es. The remaining bits after exponent bits (if any) are used for fraction which is represented by the set of fraction bits {f₁, f₂, f₃, f₄, . . . } with bit-length equals n−2−es−r. In one embodiment, if x is represented by the left shift factor LS which is the leading one LO, right shift factor RS which is the length of fraction bits BLF, and fraction f, they can be written as:

### Step 1:

$$LS = p \times {2}^{es} + s$$

$$RS = n - 2 - es - r$$

$$f = \{ \begin{matrix}{f}_{1} {f}_{2} {f}_{3} {f}_{4} … , & if leading one is not inferred \\ {1}^{′} {f}_{1} {f}_{2} {f}_{3} {f}_{4} … , & otherwise\end{matrix}$$

### Step 2:

If (LS<RS): LS=RS=0, f=f₁f₂f₃f₄ . . .

Since p is represented by TU binarization and s is represented by FL binarization where the length of the binary string is fixed to es, LS is represented by TRk binarization (pcMax=n−1, k=es). If es=0, then there is no suffix s and TRk binarization is equivalent to TU binarization.

In another embodiment, if x is represented by a unified left shift factor ULS and fraction f, they can be written as:

$$ULS = p \times {2}^{es} + s$$

$$f = \{ \begin{matrix}{f}_{1} {f}_{2} {f}_{3} {f}_{4} … , & ULS = 0 , or if leading one is not inferred \\ {1}^{′} {f}_{1} {f}_{2} {f}_{3} {f}_{4} … , & otherwise\end{matrix}$$

Since p is represented by TU binarization and s is represented by FL binarization where the length of the binary string is fixed to es, ULS is represented by TRk binarization (pcMax=n−1, k=es). If es=0, then there is no suffix s and TRk binarization is equivalent to TU binarization. For a given integer with LO be the bit location of its leading one and BLF be the bit length of fraction, when LO≥BLF≥0:

$$max ( 0 , n - 2 - es - LO ) \leq r \leq n - 2 - es$$

This integer can be represented by multiple (r, s, fraction) pairs even if n, es, and LO are fixed.

In one embodiment, the smallest r and the corresponding s and fraction are chosen as its representation so that the bits used for fraction can be maximized. In another embodiment, a proper r and the corresponding s and fraction are chosen as its representation, so that the bits after TO can be reallocated to regime and exponent bits to increase dynamic range. The reason is that since the bits after TO are always 0, these 0's can be interpreted as left shift operation and removed from fraction bits without losing accuracy.

If x is represented by the left shift factor LS, right shift factor RS, and fraction f, it can be seen from the example of 8-bit IPosit representation that IPosit (es=0) can represent up to 9-bit integer with full dynamic range. IPosit (es=1) can represent up to 13-bit integer with full dynamic range (full es bits) and 16-bit integer with limit dynamic range (partial es bits). IPosit (es=2) can represent up to 21-bit integer with full dynamic range (full es bits) and 30-bit integer with limit dynamic range (partial es bits).

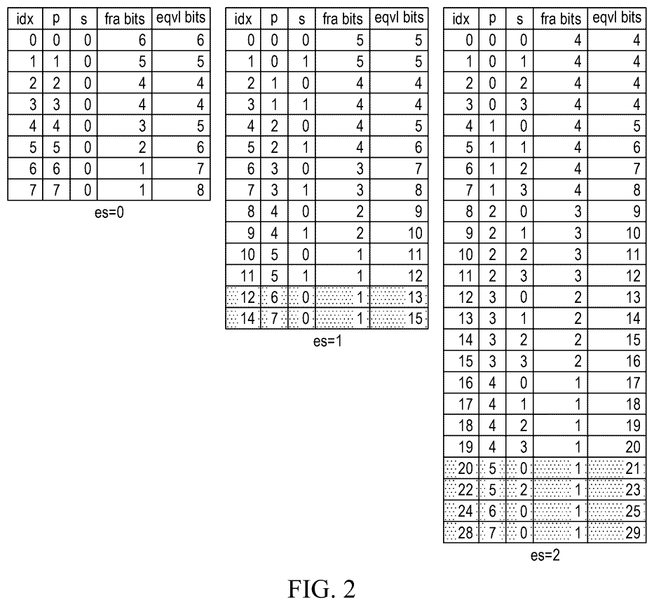

FIG. 2 is a table illustrating an example of 8-bit IPosit according to an embodiment of the disclosure. Entries marked in Gray color represent limited range. If x is represented by a unified left shift factor ULS and fraction f, it can be seen from the example of 8-bit IPosit representation that IPosit (es=0) can represent up to 9-bit integer with full dynamic range. IPosit (es=1) can represent up to 13-bit integer with full dynamic range (full es bits) and 16-bit integer with limit dynamic range (partial es bits). IPosit (es=2) can represent up to 21-bit integer with full dynamic range (full es bits) and 30-bit integer with limit dynamic range (partial es bits).

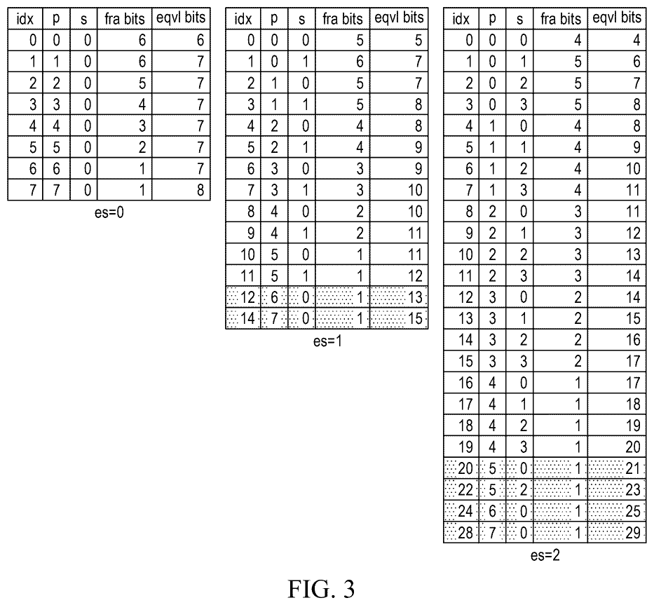

FIG. 3 is a table illustrating another example of 8-bit IPosit according to an embodiment of the disclosure. Entries marked in Gray color represent limited range.

EIPosit: Exponential Integer Posit—The present disclosure proposes an exponential integer Posit format (EIPosit) as an enhanced integer Posit format to further increase the dynamic range of integer Posit representation. The present disclosure proposes to use TEGk binarization instead of TRk binarization to represent shift factor.

The structure of an n-bit EIPosit representation with ees exponent bits is illustrated here:

| | regime bits | | | | exponent | | | | | | | | |
|---|---|---|---|---|---|---|---|---|---|---|---|---|---|
| | (R = r + 1 bits) | | | | bits, | | | | | | | | |
| | run | | | stop bit, | if any (ess = | | | | fraction | | | | |
| sign | (r bits) | | | if any | es + r bits) | | | | bits, if any | | | | |
| s | r | r | . . . | r̅ | e₁ | e₂ | . . . | eₑₛ | f₁ | f₂ | f₃ | f₄ | . . . |

n bits

### EIPosit Format

Assuming a signed number x is represented by n-bit EIPosit and its shift factor is represented by a prefix (regime bits) and a suffix (exponent bits). Let p be the unsigned integer represented by the regime bits, s (if any) be the unsigned integer represented by the exponent bits, and f (if any) be the fraction (f₁f₂f₃f₄ . . . or 1′f₁f₂f₃f₄ . . . ). Then x can be represented by left shift factor (LS) and right shift factor (RS) as:

$$x = sign ( x ) \times ( ( f ≪ LS ) ≫ RS )$$

Alternatively, x can be represented by a unified left shift factor ULS as:

$$x = sign ( x ) \times ( f ≪ ULS )$$

Regime bits are the TU binarization of p=r (pcMax=n−1). A parameter ep is defined as ep=2^{p}−1. The suffix s has ees bits, but one or more or all bits may be beyond the n-bit limit and thus have value 0. The value represented by suffix has limited range if one or more or all bits are beyond the n-bit limit and assigned with value 0. Exponent bits are the FL binarization of s and the length of the binary string is ees=es+r.

The remaining bits after exponent bits (if any) are used for fraction which is represented by the set of fraction bits {f₁, f₂, f₃, f₄, . . . } with bit-length equals n−2−es−2r. In one embodiment, if x is represented by the left shift factor LS which is the leading one LO, right shift factor RS which is the length of fraction bits BLF, and fraction f, they can be written as:

### Step 1:

$$LS = ep \times {2}^{es} + s = ( {2}^{p} - 1 ) \times {2}^{es} + s$$

$$RS = n - 2 - es - 2 r$$

$$f = \{ \begin{matrix}{f}_{1} {f}_{2} {f}_{3} {f}_{4} … , & if leading one is not inferred \\ {1}^{′} {f}_{1} {f}_{2} {f}_{3} {f}_{4} … , & otherwise\end{matrix}$$

### Step 2:

If (LS<RS): LS=RS=0, f=f₁f₂f₃f₄ . . .

Since prefix p is represented by TU binarization, and suffix s is represented by FL binarization where the length of the binary string ees=k+r=es+r, LS is represented by TEGk binarization (pcMax=n−1, k=es).

In another embodiment, if x is represented by a unified left shift factor ULS and fraction f, they can be written as:

$$ULS = ep \times {2}^{es} + s = ( {2}^{p} - 1 ) \times {2}^{es} + s$$

$$f = \{ \begin{matrix}{f}_{1} {f}_{2} {f}_{3} {f}_{4} … , & ULS = 0 , or if leading one is not inferred \\ {1}^{′} {f}_{1} {f}_{2} {f}_{3} {f}_{4} … , & otherwise\end{matrix}$$

Since prefix p is represented by TU binarization, and suffix s is represented by FL binarization where the length of the binary string ees=k+r=es+r, ULS is represented by TEGk binarization (pcMax=n−1, k=es).

For a given integer with LO be the bit location of its leading one and BLF be the bit length of fraction, when LO≥BLF≥0:

$$max ( 0 , n - 2 - es - LO ) \leq 2 r \leq n - 2 - es$$

This integer can be represented by multiple (r, s, fraction) pairs even if n, es, and LO are fixed. In one embodiment, it is proposed to choose smallest r and the corresponding s and fraction as its representation so that the bits used for fraction can be maximized. In another embodiment, is it proposed to choose a proper r and the corresponding s and fraction as its representation so that the bits after TO can be reallocated to regime and exponent bits to increase dynamic range. The reason is that since the bits after TO are always 0, these 0's can be interpreted as left shift operation and removed from fraction bits without losing accuracy.

If x is represented by the left shift factor LS, right shift factor RS, and fraction f, it can be seen from the example of 8-bit EIPosit representation that IPosit (es=0) can represent up to 16-bit integer with full dynamic range (full ees bits) and 129-bit integer with limit dynamic range (partial ees bits). EIPosit (es=1) can represent up to 15-bit integer with full dynamic range (full ees bits) and 256-bit integer with limit dynamic range (partial ees bits). EIPosit (es=2) can represent up to 29-bit integer with full dynamic range (full ees bits) and 510-bit integer with limit dynamic range (partial ees bits).

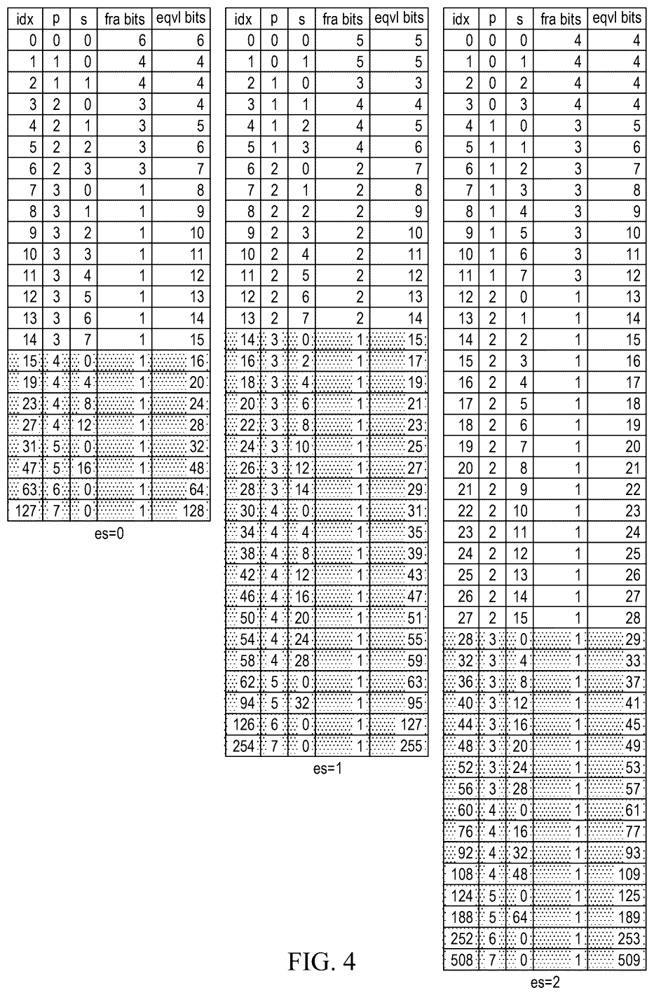

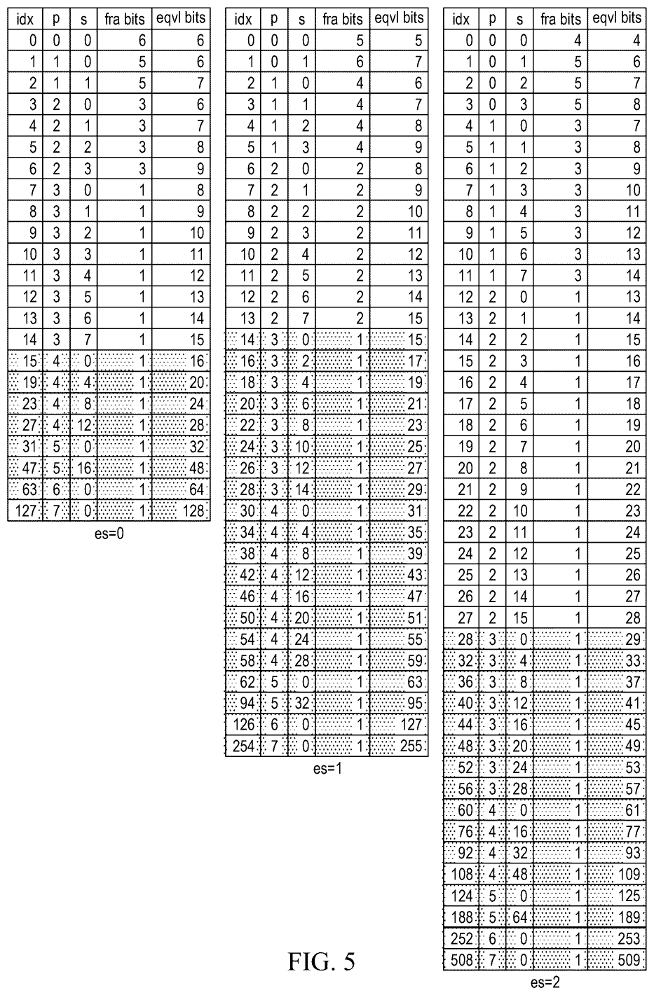

FIG. 4 is a table illustrating example of 8-bit EIPosit according to an embodiment of the disclosure. Entries marked in Gray color represent limited range. If x is represented by a unified left shift factor ULS and fraction f, it can be seen from the example of 8-bit EIPosit representation that EIPosit (es=0) can represent up to 16-bit integer with full dynamic range (full ees bits) and 129-bit integer with limit dynamic range (partial ees bits). EIPosit (es=1) can represent up to 16-bit integer with full dynamic range (full ees bits) and 256-bit integer with limit dynamic range (partial ees bits). EIPosit (es=2) can represent up to 29-bit integer with full dynamic range (full ees bits) and 510-bit integer with limit dynamic range (partial ees bits). FIG. 5 is a table illustrating another example of 8-bit EIPosit according to an embodiment of the disclosure. Entries marked in Gray color represent limited range.

Unification-based Posit (UPosit)—IPosit or EIPosit uses {sign=s, sft=(p,s), fra=(f₁f₂f₃f₄ . . . )} to represent a single integer number. The present disclosure proposes a unification-based integer Posit format to represent a group of integer numbers. In one embodiment, the leading one of full fraction f is inferred if sft>0 so f is represented by (ss′fra) where ss=(sft>0). In another embodiment, the leading one of full fraction f is not inferred so f is represented by (fra).

For a specific application such as quantized Neural Networks, model coefficients can be partitioned and quantized based on a set of rules so that coefficients in one group share the same unified value of fra, or sft, or both. In one embodiment, if both sft and fra can be shared among a group of g coefficients. It is proposed to use {(sign₁, sign₂, . . . , sign_{g}), sft, fra} or other proper format to represent these coefficients. Parameter sft can be represented by TRk binarization (UIPosit), or TEGk binarization (UEIPosit), or FL binarization (UFIPosit), or any other binarization methods. If m is total bits used in group integer representation, g bits are used to represent all signs, and e bits are used to represent sft, fra is represented by BLF=m−g−e bits.

An additional strength of this representation is that for a vector multiplication operation:

$${\sum }_{i = 1}^{g} {W}_{i} \times {A}_{i} = {\sum }_{i = 1}^{g} sign ( {s}_{i} ) \times ( {f}_{i} ≪ {sft}_{i} ) \times {A}_{i}$$

It can be rewritten to:

$$f \times {\sum }_{i = 1}^{g} sign ( {s}_{i} ) \times ( {A}_{i} ≪ sft )$$

Since sign(sᵢ)=[−1,1], and Aᵢ<<sft can be calculated using shifter instead of multiplier, this method reduces g multipliers to one multiplier for this vector multiplication operation. In another embodiment, if fra can be shared among a group of g coefficients, the present disclosure may use {(sign₁, sft₁), (sign₂, sft₂), . . . , (sign_{g}, sft_{g}), fra}, or {(sign₁, sign₂, . . . , sign_{g}), (sft₁, sft₂, . . . , sft_{g}), fra}, or other proper format to represent these coefficients. Parameter sft can be represented by TRk binarization (UIPosit), or TEGk binarization (UEIPosit), or FL binarization (UFIPosit), or any other binarization methods. If m is total bits used in group integer representation, g bits are used to represent all signs, and e; bits are used to represent sftᵢ, fra is represented by BLF=m−g−Σᵢ₌₁^{g} eᵢ bits.

An additional strength of this representation is that for a vector multiplication operation:

$${\sum }_{i = 1}^{g} {W}_{i} \times {A}_{i} = {\sum }_{i = 1}^{g} sign ( {s}_{i} ) \times ( {f}_{i} ≪ {sft}_{i} ) \times {A}_{i}$$

If f is represented by (ss′fra) where ss=(sft>0), this vector multiplication can be rewritten to:

$${\sum }_{i = 1}^{q} sign ( {s}_{i} ) \times ( ( {ss}_{i}^{′} fra ) ≪ {sft}_{i} ) \times {A}_{i} = {\sum }_{i = 1}^{q} sign ( {s}_{i} ) \times ( ( fra + ( {ss}_{i} ≪ BLF ) ) ≪ {sft}_{i} ) \times {A}_{i} = fra \times {\sum }_{i = 1}^{q} sign ( {s}_{i} ) \times ( {A}_{i} ≪ {sft}_{i} ) \times ( 1 + {ss}_{i} ≪ BLF )$$

Since sign(s)=[−1,1], ssᵢ[=[0,1], A; <<sft; and ss; <<BLF can be calculated using shifter instead of multiplier, this method reduces g multipliers to one multiplier for this vector multiplication operation. If f is represented by (fra), this vector multiplication can be rewritten to:

$${\sum }_{i = 1}^{g} sign ( {s}_{i} ) \times ( fra ≪ {sft}_{i} ) \times {A}_{i} = fra \times {\sum }_{i = 1}^{g} sign ( {s}_{i} ) \times ( {A}_{i} ≪ {sft}_{i} )$$

Since sign(s)=[−1,1] and Aᵢ<<sft; can be calculated using shifter instead of multiplier, this method reduces g multipliers to one multiplier for this vector multiplication operation.

In another embodiment, if sft can be shared among a group of g coefficients, the present disclosure may use {(sign₁, sign₂, . . . , sign_{g}), sft, (fra₁, fra₂, . . . , fra_{g})} format to represent these coefficients. Parameter sft can be represented by TRk binarization (UIPosit), or TEGk binarization (UEIPosit), or FL binarization (UFIPosit), or any other binarization methods. It is required that all fra have the same bit length. If m is total bits used in group integer representation, g bits are used to represent all signs, e bits are used to represent sft, then each fra is represented by

$$floor ( \frac{m - g - e}{g} ) bits .$$

Alternatively, if m is total bits used in group integer representation, g bits are used to represent all signs, and all fra have the same bit length f, then each sft is represented by m−g−g×f bits. In another embodiment, sign bit can also be shared among g coefficients.

The present disclosure is also related to neural network model compression and acceleration. More specifically, the method is related to dynamic quantization and unification for neural network model compression and acceleration. Deep Neural Networks (DNNs) have achieved great success in solving a wide range of applications such as semantic classification, target detection and recognition, target tracking, video quality enhancement, etc. The large model capacity of the deep network structures with huge number of parameters leads to high prediction performance, but also makes DNN models too expensive to use in practice, especially for mobile applications with strong limitations on storage, computation power, and energy consumption. It has drawn great attention how to reduce the costs of using DNNs in academia and industry.

Inference operation for deep learning system uses matrix multiplication intensively so a high-performance general matrix-matrix multiplication (GEMM) is the key for inference operation. Depending on the size of left-hand-side (lhs) matrix and right-hand-side (rhs) matrix, two GEMM routines are recognized by the industry over the last decade as the optimal GEMM solution. Both methods partition lhs matrix and rhs matrix recursively to make the best use of different characteristics of off-chip memory (such as DDR) and on-chip memory (such as multi-level cache) in modern computing platform.

Active research has been conducted in the past years to compress large DNN models. The overall target is to reduce the size of the model (i.e., the required storage) and to accelerate inference without sacrificing the performance of the original task (e.g., classification accuracy) much. Effective solutions usually require multidisciplinary knowledge from machine learning, computer architecture, hardware design, etc., and great progress has been made using different techniques, including weight pruning, weight quantization, weight unification, low-rank factorization, and knowledge distillation.

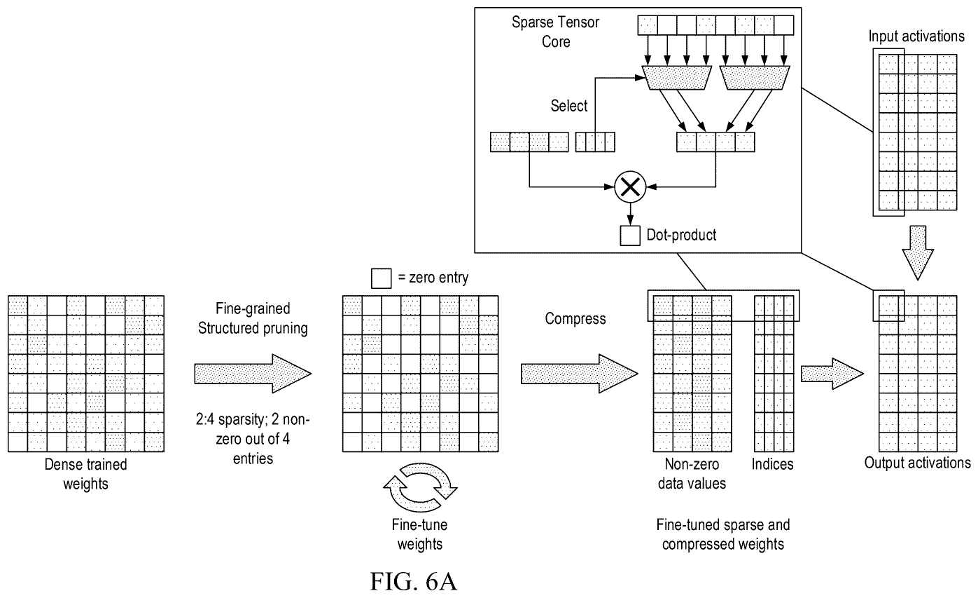

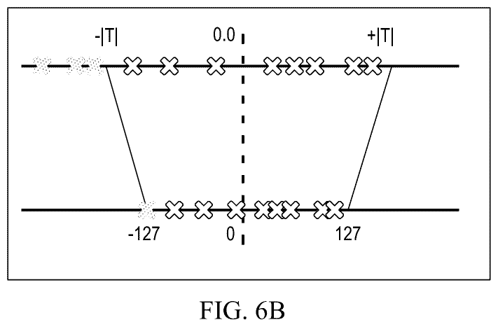

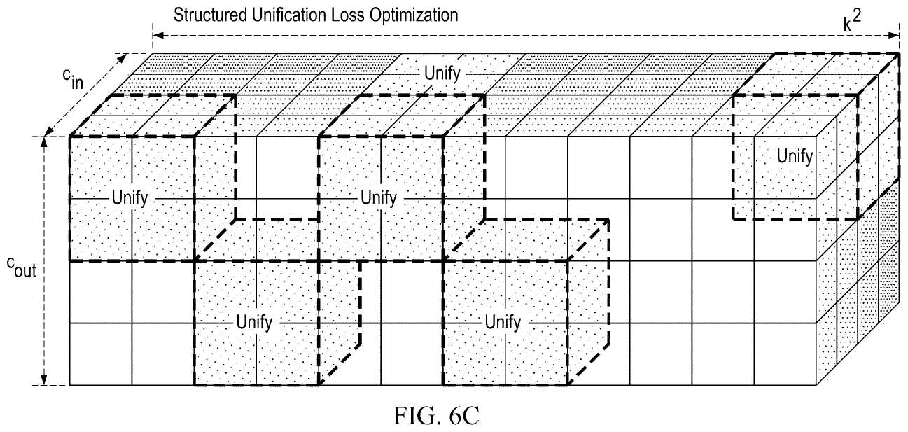

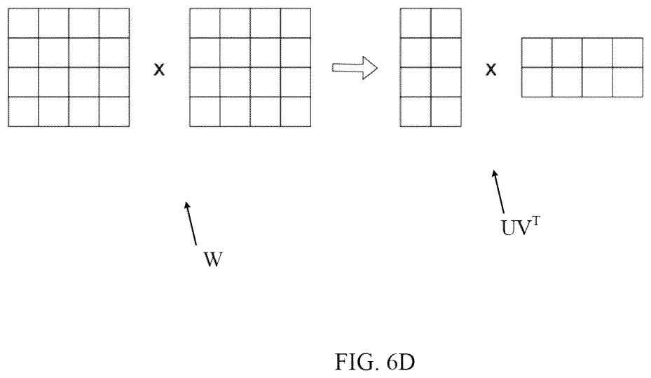

FIG. 6A illustrates weight pruning according to an embodiment of the disclosure. Weight pruning aims at removing unimportant weight coefficients in network connections. Unstructured pruning methods can achieve high sparse rate with little prediction loss. However, it cannot reduce inference computation in general, due to the random memory access pattern caused by the unstructured sparsity. Structured pruning method induces sparsity according to some hardware-friendly patterns where all weights in unimportant structures such as channels or filters are removed. However, it cannot achieve high sparse rate compared to unstructured pruning methods in general. In an example of fine-grained structured sparsity method (used in Nvidia Ampere GPU architecture), a 2:4 sparse pattern is defined where for every four adjacent coefficients, at least two coefficients at random location are forced to be zero. This method reduced the data storage and bandwidth of weight tensor by 2× and since the computation of the zero values is skipped, the processing throughput is doubled as well.

FIG. 6B illustrates weight quantization according to an embodiment of the disclosure. Weight quantization aims at reducing the number of bits of weight coefficients. Both storage and inference speed can be reduced proportionally to weight precision naturally. Because weight distribution in a layer usually follows Gaussian style bell shape distribution, the percentage of large weight coefficients is very small, but the max value of the weight coefficients is very big. Some quantization methods use KL-divergence algorithm to find an optimal saturated max value (sᵥ) for the target bit-width (bw+1) representation for each layer or each channel within one layer, and all weight coefficients in the target layer or target channel are clipped by sᵥ and quantized uniformly to bw+1-bit integer by a scale factor s=sᵥ/(2\hat{ }bw−1).

$${v}_{q} = clip ( v / s , - ( 2 \hat{} bw - 1 ) , 2 \hat{} bw - 1 ) , {v}_{rec} = {v}_{q} * s$$

Because the scale factor is shared across all coefficients in each layer or each channel, effective precision of individual coefficients within the tensor are limited and small target bit-width will cause large precision reduction and results in large network accuracy degradation. Per-vector Scaled Quantization (VS-Quant) method introduces a two-level quantization procedure where for each small vector of coefficients within a single dimension of a tensor, a separate optimal saturated max value can be found, and a corresponding scale factor can be used to reduce network accuracy loss.

FIG. 6C illustrates structured unification loss optimization according to an embodiment of the disclosure. Weight unification aims at sharing weight coefficients in network connections. Weight unification method induces weight sharing according to some hardware-friendly patterns where all weights in the predefined uniform patterns of the structure share the same absolute value (unified value). Because multiplication results can be shared within the uniform pattern, the total number of multiplications are reduced. From another perspective, the weight unification method can be seen as a generalization of weight pruning method, where the selected weights are set to unified value instead of zero. The advantage of this method is that by unifying weight coefficients instead of removing them, the network capacity and performance can be better preserved.

FIG. 6D illustrates low rank factorization according to an embodiment of the disclosure. Low-rank factorization aims at replacing a matrix W with the product UV^{T} of two smaller matrices having lower rank. It has the advantage of fast inference speed since it uses dense matrices having a regular memory access pattern. It can be combined with weight pruning method so that the two lower rank smaller matrices can have unstructured or structured sparse pattern.

For fine-grained structured sparsity method, the maximum sparse rate and throughput increase are limited to 2× due to the 2:4 sparse pattern utilized in this architecture. Removing more weights usually causes large performance drop, especially for models like MobileNet that are designed to be highly compact already.

Per-vector Scaled Quantization (VS-Quant) method introduces a two-level quantization procedure to reduce network accuracy loss. However, the scale factors calculated from the second quantization are heavily depending on the positive-negative distribution of coefficients in the target small vector. For example, it is difficult to choose the optimal saturated max value and scale factors if coefficients in the target small vector are all positive.

Weight unification method forces coefficients in a predefined uniform patterns to share the unified value. However, if the differences of the coefficients in predefined uniform pattern are large, forcing them to share the unified value may lead to suboptimal performance.

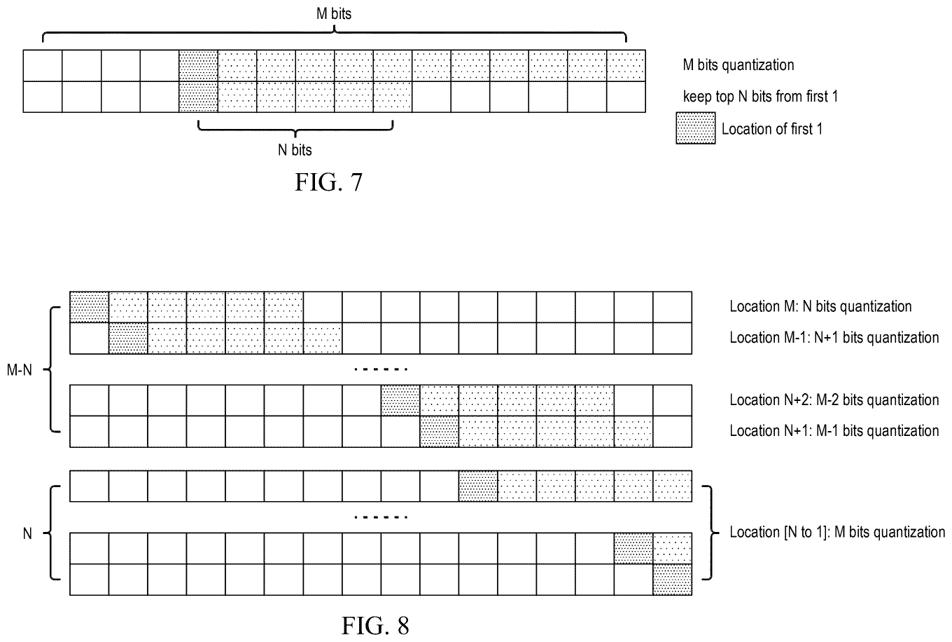

FIG. 7 illustrates dynamic quantization according to an embodiment of the disclosure. The present disclosure proposes a pseudo two-level quantization method to take advantage of the Gaussian style bell shape weight distribution in a layer. Sign-and-magnitude representation are used for the quantized integer. At the first quantization step of our proposed pseudo two-level quantization method, the present disclosure uses KL-divergence algorithm to find an optimal sᵥ for the first target bit-width (1+M, sign-and-magnitude) representation for each layer or each channel within one layer, all weight coefficients in the target layer or target channel are clipped by sᵥ and quantized uniformly to 1+M bits integer by scale factor s=sᵥ/(2\hat{ }M−1).

$${v}_{q} = clip ( v / s , - ( 2 \hat{} M - 1 ) , 2 \hat{} M - 1 ) , {v}_{rec} = {v}_{{q}^{*}} s$$

The M-bit magnitude (Q_{M}) of v_{q} is used to illustrate the second pseudo quantization step.

FIG. 8 illustrates Location M and N bits according to an embodiment of the disclosure. At the second pseudo quantization step, instead of using a second scale factor, the present disclosure simply chooses N adjacent bits from Q_{M} to generate a N-bit Q_{N}. For example, if the bit location of the most-significant-bit (msb) in Q_{M} (MSBL) is larger than N, N adjacent bits (starting from MSBL) of Q_{M} is selected as Q_{N}; otherwise, the last N adjacent bit of Q_{M} is selected as Q_{N}. The reconstructed Q_{M} can be obtained using below equation:

$$= {Q}_{N} ≪ shft , shft = max ( 0 , MSBL - N )$$

| | | | | | | |
|---|---|---|---|---|---|---|
| MSBL | <=N | N + 1 | N + 2 | . . . | M-1 | M |
| shft | 0 | 1 | 2 | . . . | M-N-1 | M-N |
| Equivalent quantization | M | M-1 | M-2 | . . . | N + 1 | N |
| bit-width | | | | | | |

Parameter shft is an integer shift factor whose range is [0, M−N] and max bit-width (bws) is log₂(M−N+1). It can be seen from the chart that shft and equivalent quantization bit-width in the second pseudo quantization step are dynamically adjusted based on MSBL. The equivalent quantization bit-width decreases when the value of MSBL increases which means that the second pseudo quantization error is large for coefficients with large MSBL, and the second pseudo quantization error is small for coefficients with small MSBL. For coefficients whose MSBL<=N, the second pseudo quantization error is zero and the full M-bit quantization accuracy is maintained. Given that the weight distribution in a layer usually follows Gaussian style bell shape distribution where the percentage of smaller coefficients is more than that of larger coefficients, our pseudo two-level quantization method can maintain better quantization accuracy compared to other methods.

Dynamic Unification—In the pseudo two-level quantization method, the reconstructed M-bit Q_{M} can be represented by a N-bit Q_{N} and a bws-bit shft (max N+bws bits) as [symbol] =Q_{N}<<shft. Multiplication for each coefficient is reduced from M-bit to N-bit, the storage and bandwidth for each coefficient are also reduced from M bits to N+bws bits. To further reduce the storage resource, bandwidth resource, and multiplier/adder resources, the present disclosure proposes to define one or more uniform patterns so that all coefficients in the predefined uniform patterns of the structure share the same shft, or the same Q_{N}, or the same unified Q_{N}, or combination of the same shft and Q_{N} or unified Q_{N}.

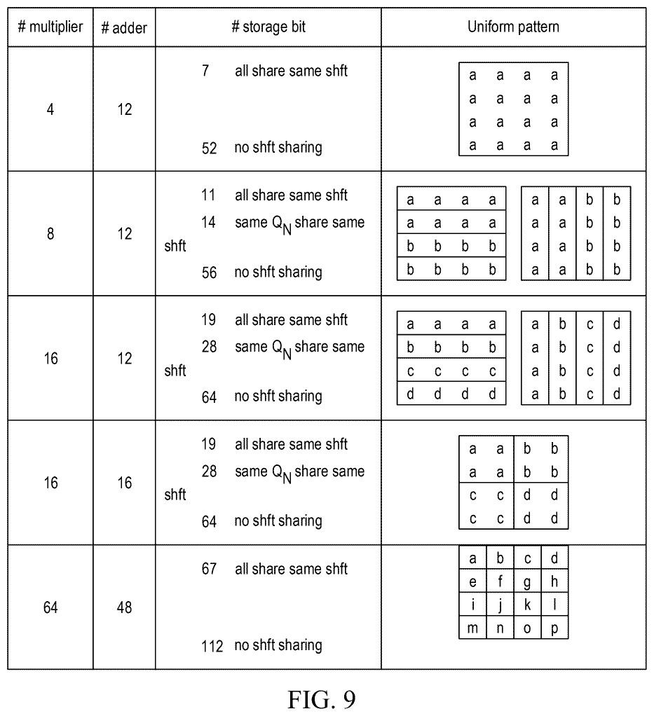

FIG. 9 illustrates an example of a predefined uniform patterns structure according to an embodiment of the present disclosure. The shape of the uniform structure can be defined as a multi-dimensional tensor, a three-dimensional (3D) tensor, a two-dimensional (2D) matrix or a one-dimensional (1D) vector. Take an 8-bit 4×4 2D matrix as example, if Q_{M} (M=8) is represented by Q_{N} (N=4) and shft=3 and no sharing among coefficients, the storage for this matrix is 4×4×7=112 bits, a general [4, 4]×[4, 4] matrix multiplication uses 64 multipliers and 48 adders. If all coefficients in the predefined uniform patterns of the structure share the same shft, or the same Q_{N}, or the same unified Q_{N}, or combination of the same shft and Q_{N} or unified Q_{N}, the storage resource, bandwidth resource, and multiplier/adder resources can be further reduced simultaneously.

Several uniform pattern for [4, 4] lhs matrix and the corresponding storages, multipliers, and adders count are listed as example. For a multiplication operation [symbol] *A=(Q_{N}<<shft)*A=Q_{N}*(A<<shft), the term A<<shft can be calculated using shifter instead of multiplier. If coefficient polarity is taken into consideration, assuming the msb of Q_{M} and Q_{N} is a sign bit, for a multiplication operation [symbol] *A=((−1)\hat{ }sign*abs (Q_{N})<<shft)*A=abs (Q_{N})*((−1)\hat{ }md sign*(A<<shft)) where sign is a 1 bit flag to indicate the polarity of Q_{N}, because (−1)\hat{ }sign=[1, −1], the term (−1)\hat{ }sign*(A<<shft) can be calculated without using any dedicated multiplier as well.

Symbol [a-p] in the chart represent Q_{N} or unified Q_{N}, and the patterns formed by these coefficients represent the examples of different uniform patterns. It can be seen from the chart that for general [4, 4]×[4, 4] matrix multiplication, choosing different uniform pattern can result in multiplier reduction from 64 to 16, 8 or 4, adder reduction from 48 to 12, and storage and bandwidth reduction from 112 bits to 67, 64, 56, 52, 28, 19, 14, 11, or 7 bits.

The parameter Q_{N} represents small variance distribution of the coefficients in unified pattern where the variance is within N bits, the parameter shft represents large variance distribution of the coefficients in unified pattern where the variance is within 2\hat{ }bws bits. The present disclosure proposes to adjust both Q_{N} and shft jointly so that total reconstruction error of coefficients in the structure is minimized. If the adjusting algorithm ensures that the first magnitude bit of all Q_{N} are always one when shft is not zero, the present disclosure can use one less bit to represent Q_{N} when shft is not zero by inferring this magnitude bit instead of explicitly signaling it.

Dynamic Unified Sparsity—In an example of fine-grained structured sparsity method (used in Nvidia Ampere GPU architecture), a 2:4 sparse pattern is defined where for every four adjacent coefficients, at least two coefficients at random location are forced to be zero. The maximum sparse rate and throughput increase are limited to 2× due to the 2:4 sparse pattern utilized in this architecture, and removing more weights usually causes large performance drop. To further increase the throughput, the present disclosure proposes that after the target tensor is reshaped by removing zero coefficients and keeping only nonzero coefficients, dynamic unification is performed on the reshaped tensor so that the storage resource, bandwidth resource, and multiplier/adder resources can be further reduced.

Dynamic Unified Low-rank Factorization—In low-rank factorization method, a matrix W is represented by the product UV^{T} of two smaller matrices having lower rank. Optionally, it can be combined with weight pruning method so that the two lower rank smaller matrices can have unstructured or structured sparse pattern. The present disclosure proposes to apply dynamic unification method to the dense or sparse smaller matrices UV so that the storage resource, bandwidth resource, and multiplier/adder resources can be further reduced.

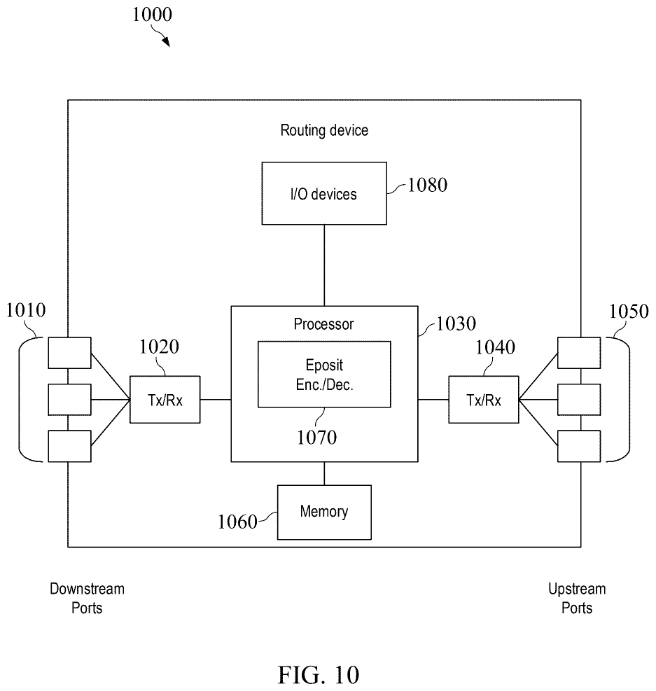

FIG. 10 is a schematic diagram of a routing device 1000 according to an embodiment of the disclosure. The routing device 1000 is suitable for implementing the disclosed embodiments as described herein. In an embodiment, the routing device 1000 may be a router, a switch, a node, or another communication device configured to process Internet traffic.

The routing device 1000 comprises ingress ports 1010 (or input ports 1010) and receiver units (Rx) 1020 for receiving data; one or more processors, logic units, or central processing units (CPUs) 1030 to process the data; transmitter units (Tx) 1040 and egress ports 1050 (or output ports 1050) for transmitting the data; and a memory 1060 for storing the data. The routing device 1000 may also comprise optical-to-electrical (OE) components and electrical-to-optical (EO) components coupled to the ingress ports 1010, the receiver units 1020, the transmitter units 1040, and the egress ports 1050 for egress or ingress of optical or electrical signals.

The one or more processors 1030 are implemented by hardware and software. The processor(s) 1030 may be implemented as one or more CPU chips, cores (e.g., as a multi-core processor), FPGAs, ASICs, and DSPs. The processor(s) 1030 is in communication with the ingress ports 1010, receiver units 1020, transmitter units 1040, egress ports 1050, and memory 1060. The one or more processor(s) 1030 include an Exponential Posit (EPosit) coding device 1070. The E-Posit coding device 1070 comprises encoders and decoders that implement the disclosed EPosit representation described above. The inclusion of the E-Posit coding device 1070 therefore provides a substantial improvement to the functionality of the routing device 1000 and effects a transformation of the routing device 1000 to a different state.

The memory 1060 may comprise one or more disks, tape drives, and solid-state drives and may be used as an over-flow data storage device, to store programs when such programs are selected for execution, and to store instructions and data that are read during program execution. The memory 1060 may be, for example, volatile and/or non-volatile and may be a read-only memory (ROM), random access memory (RAM), ternary content-addressable memory (TCAM), and/or static random-access memory (SRAM).

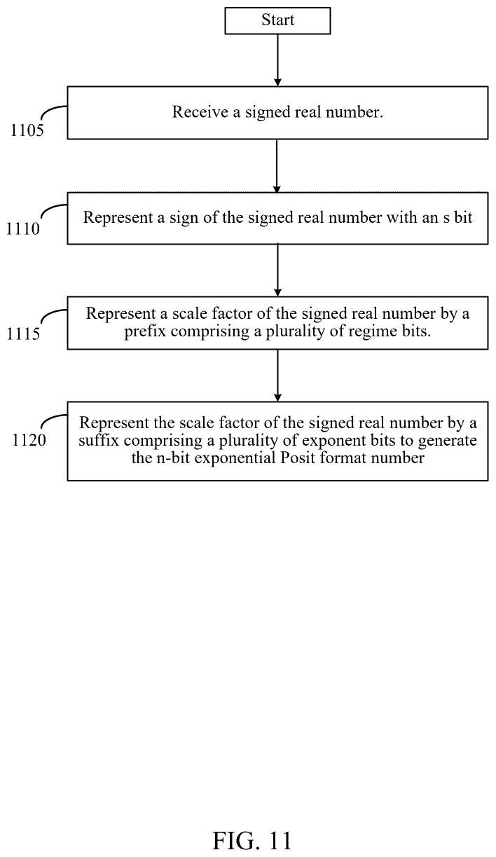

FIG. 11 is a flowchart of a method for converting a signed real number to an n-bit exponential Posit format number according to an embodiment of the disclosure. In 1105, the E-Posit encoder/decoder unit 1070 receives the signed real number. In 1110, the E-Posit encoder/decoder unit 1070 represents a sign of the signed real number with an s bit. In 1115, the E-Posit encoder/decoder unit 1070 represents a scale factor of the signed real number by a prefix comprising a plurality of regime bits. In 1120, the E-Posit encoder/decoder unit 1070 represents the scale factor of the signed real number by a suffix comprising a plurality of exponent bits to generate the n-bit exponential Posit format number.

While several embodiments have been provided in the present disclosure, it should be understood that the disclosed systems and methods might be embodied in many other specific forms without departing from the spirit or scope of the present disclosure. The present examples are to be considered as illustrative and not restrictive, and the intention is not to be limited to the details given herein. For example, the various elements or components may be combined or integrated in another system or certain features may be omitted, or not implemented.

In addition, techniques, systems, subsystems, and methods described and illustrated in the various embodiments as discrete or separate may be combined or integrated with other systems, modules, techniques, or methods without departing from the scope of the present disclosure. Other items shown or discussed as coupled or directly coupled or communicating with each other may be indirectly coupled or communicating through some interface, device, or intermediate component whether electrically, mechanically, or otherwise. Other examples of changes, substitutions, and alterations are ascertainable by one skilled in the art and could be made without departing from the spirit and scope disclosed herein.

What is claimed is:

1. A method for converting a signed real number to an n-bit exponential Posit format number implemented by an exponential Posit coding device, comprising:
receiving the signed real number in the exponential Posit coding device;
representing a sign of the signed real number with an s bit;
representing a scale factor of the signed real number by a prefix comprising a plurality of regime bits; and
representing the scale factor of the signed real number by a suffix comprising a plurality of exponent bits to generate the n-bit exponential Posit format number.

2. The method of claim 1, further comprising storing the n-bit exponential Posit format number in a memory by the exponential Posit coding device, wherein storage of the n-bit exponential Posit format number in the memory uses less bits than storage of the signed real number in the memory.

3. The method of claim 1, further comprising transmitting, by the exponential Posit coding device, the n-bit exponential Posit format number toward a decoding device, wherein transmission of the n-bit exponential Posit format number uses less bandwidth than transmission of the signed real number.

4. The method of claim 1, further comprising representing a fraction of the signed real number with a plurality of fraction bits.

5. The method of claim 1, wherein the regime bits include an integer value and a regime sign.

6. The method of claim 1, wherein the n-bit exponential Posit format number has a structure:

| | regime bits | | | | | exponent | | | | | | | | |
|---|---|---|---|---|---|---|---|---|---|---|---|---|---|---|
| | re- | | | | stop | bits, if any | | | | fraction | | | | |
| | gime | run | | | bit, | (ees = es + r | | | | bits, if | | | | |
| sign | sign | (r bits) | | | if any | bits) | | | | any | | | | |
| s | sᵣ | r | r | . . . | r̅ | e₁ | e₂ | . . . | eₑₑₛ | f₁ | f₂ | f₃ | f₄ | . . . |

n bits

7. A method for converting an integer number to an n-bit integer Posit format number implemented by an exponential Posit coding device, comprising:
receiving the integer number in the exponential Posit coding device;
representing a sign of the integer number with an s bit;
representing a shift factor of the integer number by a prefix comprising a plurality of regime bits; and
representing the shift factor of the integer number by a suffix comprising a plurality of exponent bits to generate the n-bit exponential Posit format number

8. The method of claim 7, further comprising representing a fraction of the integer number with a plurality of fraction bits.

9. The method of claim 7, wherein the regime bits comprise an unsigned integer value and the exponent bits represent an unsigned integer.

10. The method of claim 7, wherein the n-bit exponential Posit format number has a structure:

| | regime bits | | | | | | | | | | | | |
|---|---|---|---|---|---|---|---|---|---|---|---|---|---|
| | (R = r + 1 bits) | | | | exponent | | | | | | | | |
| | run | | | stop bit, | bits, if any | | | | fraction | | | | |
| sign | (r bits) | | | if any | (es bits) | | | | bits, if any | | | | |
| s | r | r | . . . | r̅ | e₁ | e₂ | . . . | eₑₛ | f₁ | f₂ | f₃ | f₄ | . . . |

n bits

11. An apparatus for converting a signed real number to an n-bit exponential Posit format number, comprising:
a storage device; and
one or more processors coupled to the storage device and configured to execute instructions on the storage device such that when executed, cause the apparatus to:
receive the signed real number in the apparatus;
represent a sign of the signed real number with an s bit;
represent a scale factor of the signed real number by a prefix comprising a plurality of regime bits; and
represent the scale factor of the signed real number by a suffix comprising a plurality of exponent bits to generate the n-bit exponential Posit format number.

12. The apparatus of claim 11, wherein execution of the instructions further cause the apparatus to store the n-bit exponential Posit format number in a memory, wherein storage of the n-bit exponential Posit format number in the memory uses less bits than storage of the signed real number in the memory.

13. The apparatus of claim 11, wherein execution of the instructions further cause the apparatus to transmit, by an encoding device, the n-bit exponential Posit format number toward a decoding device, wherein transmission of the n-bit exponential Posit format number uses less bandwidth than transmission of the signed real number.

14. The apparatus of claim 11, further comprising representing a fraction of the signed real number with a plurality of fraction bits.

15. The apparatus of claim 11, wherein the regime bits include an integer value and a regime sign.

16. The apparatus of claim 11, wherein the n-bit exponential Posit format number has a structure:

| | regime bits | | | | | exponent | | | | | | | | |
|---|---|---|---|---|---|---|---|---|---|---|---|---|---|---|
| | re- | | | | stop | bits, if any | | | | fraction | | | | |
| | gime | run | | | bit, | (ees = es + r | | | | bits, if | | | | |
| sign | sign | (r bits) | | | if any | bits) | | | | any | | | | |
| s | sᵣ | r | r | . . . | r̅ | e₁ | e₂ | . . . | eₑₑₛ | f₁ | f₂ | f₃ | f₄ | . . . |

n bits

17. An apparatus for converting an integer number to an n-bit integer Posit format, comprising:
a storage device; and
one or more processors coupled to the storage device and configured to execute instructions on the storage device such that when executed, cause the apparatus to:
receive the integer number in the apparatus;
represent a sign of the integer number with an s bit;
represent a shift factor of the integer number by a prefix comprising a plurality of regime bits; and
represent the shift factor of the integer number by a suffix comprising a plurality of exponent bits to generate an n-bit exponential Posit format number

18. The apparatus of claim 17, wherein execution of the instructions further cause the apparatus to represent a fraction of the integer number with a plurality of fraction bits.

19. The apparatus of claim 17, wherein the regime bits comprise an unsigned integer value and the exponent bits represent an unsigned integer.

20. The apparatus of claim 17, wherein the n-bit exponential Posit format number has a structure:

| | regime bits | | | | | | | | | | | | |
|---|---|---|---|---|---|---|---|---|---|---|---|---|---|
| | (R = r + 1 bits) | | | | exponent | | | | | | | | |
| | run | | | stop bit, | bits, if any | | | | fraction | | | | |
| sign | (r bits) | | | if any | (es bits) | | | | bits, if any | | | | |
| s | r | r | . . . | r̅ | e₁ | e₂ | . . . | eₑₛ | f₁ | f₂ | f₃ | f₄ | . . . |

n bits
